(19) United States
(12) Patent Application Publication
(10) Pub. No.: US 2026/0319124 A1
(43) Pub. Date: Oct. 15, 2026

(54) REAL TIME LOG DATA INVERSION UNCERTAINTY ESTIMATION

(71) Applicant: HALLIBURTON ENERGY SERVICES, INC., Houston, TX (US)

(72) Inventors: Wei Shao, Houston, TX (US); Songhua Chen, Houston, TX (US)

(73) Assignee: HALLIBURTON ENERGY SERVICES, INC., Houston, TX (US)

(21) Appl. No.: 19/314,559

(22) Filed: Aug. 29, 2025

Related U.S. Application Data
(60) Provisional application No. 63/787,403, filed on Apr. 11, 2025.

(51) Int. Cl. G01V 3/32; E21B 43/119; E21B 44/00; E21B 47/00; G01R 33/50

(52) U.S. Cl. CPC G01V 3/32; E21B 43/119; E21B 44/00; E21B 47/00; G01R 33/50

(57) ABSTRACT

Provided herein is a method for estimating nuclear magnetic resonance (NMR) spectral uncertainty in real-time. The method can include receiving NMR log data from an NMR measurement device, extracting, for a given depth, NMR measurement noises from the NMR log data of adjacent depths, simulating NMR responses at the given depth by superimposing the NMR measurement noises of the adjacent depths to the NMR log data of the given depth, determining, from the simulated NMR responses, NMR T₁ and/or T₂ distributions for each of the simulated NMR responses, determining, via the NMR T₁ and/or T₂ distributions, an NMR spectral uncertainty for the given depth, and determining a drilling path for a wellbore and/or a perforation interval based on the NMR T₁ and/or T₂ distributions and the NMR spectral uncertainty.

### CROSS-REFERENCE TO RELATED APPLICATIONS

This application claims priority benefit to U.S. Provisional Application No. 63/787,403, filed Apr. 11, 2025, the contents of which are entirely incorporated by reference herein.

### FIELD

The present disclosure relates generally to systems and methods for determining NMR spectral uncertainty.

### BACKGROUND

In many oil drilling operations, nuclear magnetic resonance (NMR) relaxation time distributions (T₁ and T₂ distributions) provide essential petrophysical properties of a formation, such as total and partial porosity and permeability. These petrophysical properties are utilized to determine drilling locations, perforation intervals, and other drilling parameters.

### BRIEF DESCRIPTION OF THE DRAWINGS

Implementations of the present technology will now be described, by way of example only, with reference to the attached figures, wherein:

FIG. 1A is a schematic diagram of an example logging while drilling (LWD) wellbore operating environment in accordance with various aspects of the disclosure.

FIG. 1B is a diagram of an example downhole environment having tubulars, in accordance with various aspects of the disclosure.

FIG. 2 illustrates a flow chart of a method for estimating NMR spectral uncertainty in real-time.

FIG. 3 is a diagram illustrating an example of a system for implementing certain aspects of the present disclosure.

FIG. 4 is a workflow diagram of an NMR uncertainty estimation using a Monte Carlo method.

FIG. 5 illustrates a pore size distribution pattern (ground truth) for a Monte Carlo simulation.

FIG. 6 illustrates simulated T₂ distributions.

FIGS. 7A-7B illustrate NMR spectral uncertainty and mean T₂ distributions estimated with a Monte Carlo method with a regularization parameter value of 1.

FIGS. 8A-8C illustrate histograms of the variances of fitting errors with three different regularization parameter values for the echo train TW of 10000 ms.

FIGS. 9A-9B illustrates and ensemble of T₂ distributions and NMR spectral uncertainties of NMR log data derived with a depth-by-depth method.

FIGS. 10A-10B illustrate comparisons of NMR spectral uncertainties derived with a Monte Carlo method and a depth-by-depth method.

FIGS. 11A-11D illustrate comparisons of NMR spectral uncertainties of two NMR activation sets without considering the regularization terms.

FIGS. 12A-12D illustrate comparisons of NMR spectral uncertainties of two NMR activation sets with the regularization parameter values set to be 1 for two activation sets.

FIGS. 13A-13B illustrates NMR spectral uncertainties with a regularization parameter value of 10.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

Additional features and advantages of the disclosure will be set forth in the description which follows, and in part will be obvious from the description, or can be learned by practice of the principles disclosed herein. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The common practice of NMR log data inversion involves a large-scale ill-posed problem with non-negative constraints, which makes it challenging to estimate NMR spectral uncertainty with analytical approaches. Monte Carlo methods can be an effective technique to assess the uncertainties of NMR data processing. However, Monte Carlo methods need to be repeated multiple times for statistical analysis. Further, Monte Carlo methods are limited to synthetic data. Based on the mathematical formulations of NMR data processing, a method to extract NMR measurement errors from NMR log data and create an ensemble of simulated NMR distributions with the extracted NMR measurements errors for a given log depth was developed. The uncertainties of the NMR spectrum and pore typing are then derived from the ensemble of simulated NMR distributions. The method provided herein is computationally efficient for processing NMR log data in real-time.

Provided herein are systems and methods operable to characterize NMR log data inversion uncertainty in real-time to enable a full uncertainty analysis in the real-time settings, by addressing spectral resolution errors in addition to statistical uncertainties.

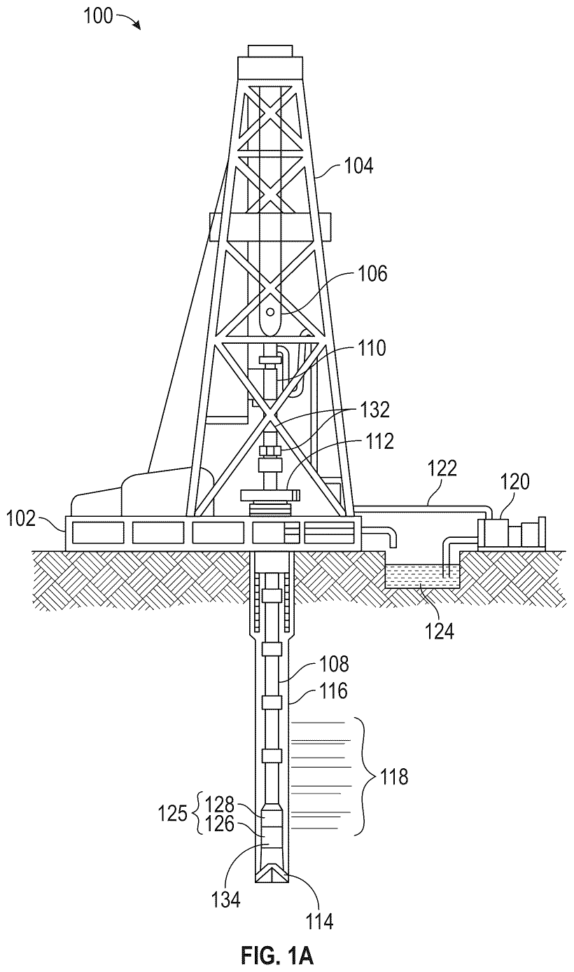

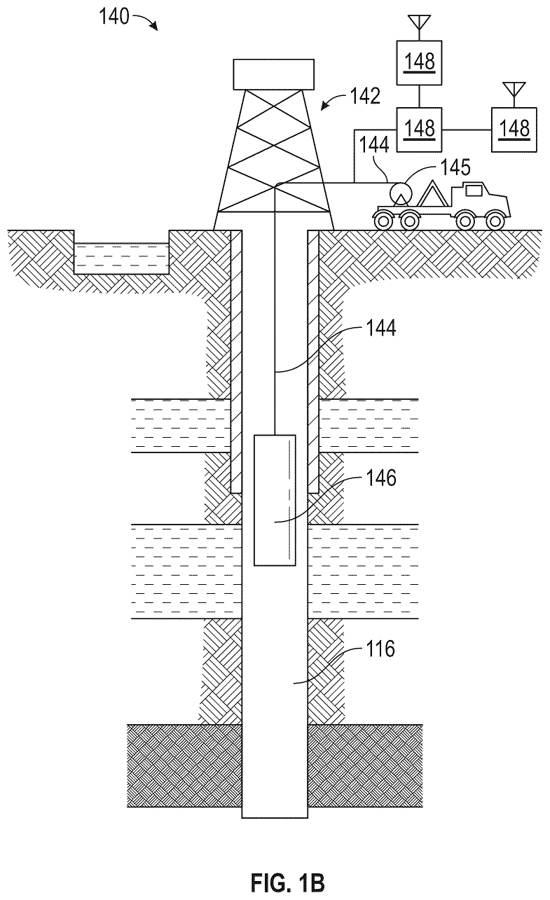

FIG. 1A is a schematic diagram of an example logging while drilling (LWD) operating environment of a well site, in accordance with various aspects of the disclosure.

In some aspects, a drilling arrangement is shown that exemplifies a LWD configuration in a wellbore drilling scenario 100. The LWD typically incorporates sensors that acquire formation data. The drilling arrangement of FIG. 1A also exemplifies measurement while drilling (MWD) and utilizes sensors to acquire data from which the wellbore's path and position in three-dimensional space may be determined. FIG. 1A shows a drilling platform 102 equipped with a derrick 104 that supports a hoist 106 for raising and lowering a drill string 108. The hoist 106 suspends a top drive 110 suitable for rotating and lowering the drill string 108 through a well head 112. A drill bit 114 may be connected to the lower end of the drill string 108. As the drill bit 114 rotates, the drill bit 114 creates a wellbore 116 that passes through one or more subterranean formations 118. A pump 120 circulates drilling fluid through a supply pipe 122 to top drive 110, down through the interior of the drill string 108, and out orifices in the drill bit 114 into the wellbore. The drilling fluid returns to the surface via the annulus around the drill string 108, and into a retention pit 124. The drilling fluid transports cuttings from the wellbore 116 into the retention pit 124 and the drilling fluid's presence in the annulus aids in maintaining the integrity of the wellbore 116. Various materials may be used for drilling fluid, including oil-based fluids and water-based fluids.

In some aspects, one or more logging tools 126 may be integrated into the bottom-hole assembly 125 near the drill bit 114. As the drill bit 114 extends the wellbore 116 through the subterranean formations 118, logging tools 126 collect measurements relating to various formation properties as well as the orientation of the tool and various other drilling conditions. In some cases, the logging tools interface with various sensors and equipment. The bottom-hole assembly 125 may also include a telemetry sub 128 to transfer measurement data to a surface receiver 132 and to receive commands from the surface. In at least some cases, the telemetry sub 128 communicates with a surface receiver 132 using mud pulse telemetry. In some instances, the telemetry sub 128 does not communicate with the surface, but rather stores logging data for later retrieval at the surface when the logging assembly is recovered.

Each of the logging tools 126 may include one or more tool components spaced apart from each other and communicatively coupled by one or more wires and/or another communication arrangement. The logging tools 126 may also include one or more computing devices communicatively coupled with one or more of the tool components. The one or more computing devices may be configured to control or monitor the performance of the tool, process logging data, and/or carry out one or more aspects of the methods and processes of the present disclosure.

In at least some instances, one or more of the logging tools 126 may communicate with a surface receiver 132 by a wire, such as a wired drill pipe. In other cases, the one or more of the logging tools 126 may communicate with a surface receiver 132 by wireless signal transmission, such as ground penetrating radar. In at least some cases, one or more of the logging tools 126 may receive electrical power from a wire that extends to the surface, including wires extending through a wired drill pipe.

In some aspects, a collar 134 is a frequent component of a drill string 108 and generally resembles a very thick-walled cylindrical pipe, typically with threaded ends and a hollow core for the conveyance of drilling fluid. In some cases, multiple collars 134 may be included in the drill string 108 and are constructed and intended to be heavy to apply weight on the drill bit 114 to assist the drilling process. Because of the thickness of the collar's wall, pocket-type cutouts or other type recesses may be provided into the collar's wall without negatively impacting the integrity (strength, rigidity, and the like) of the collar 134 as a component of the drill string 108.

FIG. 1B is a diagram of an example downhole environment having tubulars in accordance with various aspects of the disclosure. In some aspects, an example system 140 is depicted for conducting downhole measurements after at least a portion of a wellbore has been drilled and the drill string removed from the well. A downhole tool is shown having a tool body 146 to perform logging, measurements, and/or other operations. For example, instead of using the drill string 108 of FIG. 1A to lower a tool body 146, which may contain sensors and/or other instrumentation for detecting and logging nearby characteristics and conditions of the wellbore 116 and surrounding formations, a wireline conveyance 144 may be used.

The tool body 146 may be lowered into the wellbore 116 by wireline conveyance 144. The wireline conveyance 144 may be anchored in the drill rig 142 or by a portable device such as a truck 145. The wireline conveyance 144 may include one or more wires, slicklines, cables, and/or the like, as well as tubular conveyances such as coiled tubing, joint tubing, or other tubulars.

The wireline conveyance 144 provides power and support for the tool, as well as enabling communication between processing systems 148 on the surface. In some examples, the wireline conveyance 144 may include electrical and/or fiber optic cabling for performing any communications. The wireline conveyance 144 is sufficiently strong and flexible to tether the tool body 146 through the wellbore 116, while also permitting communication through the wireline conveyance 144 to one or more of the processing systems 148, which may include local and/or remote processors. In some cases, power may be supplied via the wireline conveyance 144 to meet the power requirements of the tool. For slickline or coiled tubing configurations, power may be supplied downhole with a battery or via a downhole generator.

The systems and methods described herein can be used to determine the locations to drill in accordance with the equipment described in FIGS. 1A-1B.

Nuclear Magnetic Resonance (NMR) relaxation time distributions (T₂ or T₁) provide essential petrophysical properties of the formation, such as total and partial porosity, permeability, and other petrophysical properties. However, the accuracies of the petrophysical properties derived from NMR relaxation time distribution are highly affected by NMR log data qualities (e.g., signal to noise ratio (SNR) of NMR logging measurements). In addition to SNR, the accuracies of NMR based petrophysical properties can also be affected by multiple other factors, including NMR activation sequences, inversion methods, and formation types.

In current practice, the uncertainties of NMR based interpretation are mainly inferred from the fitting errors of NMR regularization inversion, and the repeatability of NMR total porosities. However, the fitting errors and the uncertainty of NMR total porosity do not reveal NMR T₂ or T₁ spectral uncertainty, which is necessary to derive the uncertainties of NMR based pore typing (e.g., the partial porosities).

The uncertainty estimation of NMR based petrophysical properties are further complicated by the regularization in the current NMR inversion process. In general, the larger the regularization, the smaller the uncertainty, and vice versa. Hence, the regularization conceals the true uncertainty of NMR spectrum. Additionally, a larger regularization introduces a large bias to NMR inversion solution.

To balance the uncertainty and bias of NMR inversion, the value of the regularization parameter is typically selected to ensure the repeatability of NMR total porosity within 1.0 p.u. However, this practice does not directly relate to NMR T₂ or T₁ spectral uncertainty, and the repeatability of NMR partial porosities.

Statistical methods, such as Simulated Annealing and Bayesian inversion, have been used to circumvent the need of using regularization terms in NMR inversion, and provide the “true” NMR spectral uncertainty. However, these statistical methods are computationally expensive and time consuming and are therefore not suitable for processing NMR log data in real time.

A Monte Carlo method can be used to assess the uncertainties of NMR data processing. For a given NMR data activation sequence and a pore size distribution pattern, the Monte Carlo method can simulate NMR responses for a specified SNR. NMR relaxation time distributions (T₂, or T₁) can then be derived with NMR regularization inversion for the simulated NMR responses. The Monte Carlo simulation process can be repeated multiple times (e.g., three or more) to assemble the possible NMR relaxation time distributions for the specified SNR. Statistical analysis can then be applied to the ensemble of NMR relaxation time distributions to estimate the NMR spectral uncertainties.

In comparison to Simulated Annealing and Bayesian inversion methods, the computational cost of the Monte Carlo method is low. However, the need for repeating NMR response simulations limits the Monte Carlo method to NMR synthetic data. Therefore, systems and methods are provided herein which adapts the Monte Carlo method to estimate uncertainties of NMR inversion and pore typing for NMR log data in real-time. Further, the systems and methods can be extended to estimate the uncertainties of NMR inversion while removing the effect of regularization.

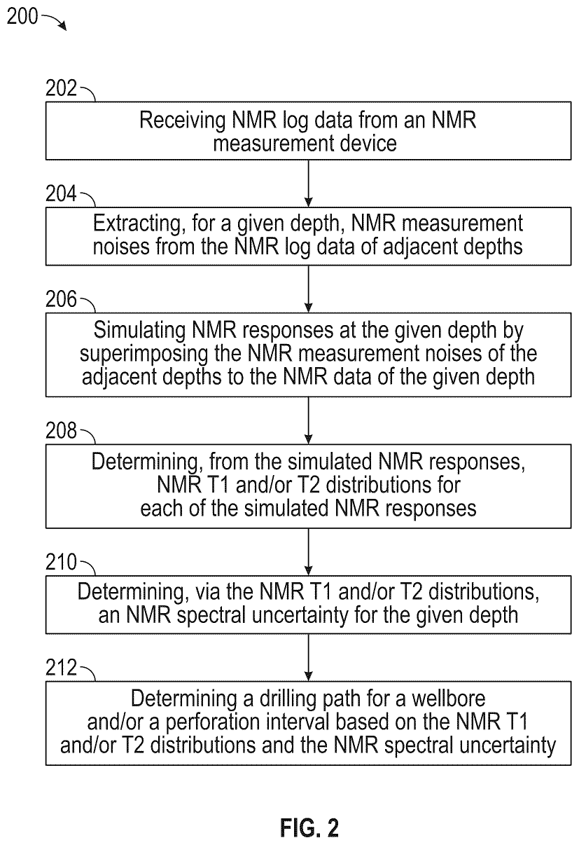

FIG. 2 illustrates a method 200 for estimating NMR spectral uncertainty in real-time. The method 200 can use NMR measurement errors from adjacent depths to form an ensemble of simulated NMR distributions with the extracted NMR measurement errors for a given depth. The NMR spectral uncertainty and pore typing can be derived from the ensemble of simulated NMR distributions.

At block 202, the method 200 can begin by receiving NMR log data from an NMR measurement device. The NMR measurement device can include any NMR measurement device that is operable to measure and record NMR log data within a wellbore. In some examples, the NMR log data can include at least a wait time (TW), inter-echo spacing (TE), a number of echoes (NE), and a number of repeats of the NMR activation set. In some examples, the NMR log data can be processed such that NMR data for certain depths are isolated. For example, the NMR log data can be isolated for various depths at certain intervals.

At block 204, the method 200 can include extracting, for a given depth, NMR measurement noises from the NMR log data for adjacent depths. The adjacent depths can be

$${\{ {d}_{j} \}}_{j = i - N}^{j = i + N} ,$$

represented by where N is the size of adjacent depths of the given depth dᵢ. The NMR measurement noises can be approximated by fitting errors of NMR regularization inversions having a regularization parameter. The mathematical process for approximating NMR measurement noises with the fitting errors of NMR regularization inversions is described below.

Assuming

$${\{ {Y}_{i} , {d}_{i} \}}_{i = 1}^{N}$$

are the NMR log data for a given NMR activation set, Yᵢ is NMR log response, NMR echo trains, at depth dᵢ.

$${\{ {X}_{i} \}}_{i = 1}^{N}$$

are the corresponding NMR relaxation time distributions derived from NMR log data through the regularized NMR inversion as described in Eq. 1.

$${min}_{{X}_{i} \geq 0} \{ {\vert {AX}_{i} - {Y}_{i} \vert}^{2} + α {\vert {LX}_{i} \vert}^{2} \} \qquad ( 1 )$$

Where A is NMR forward modeling matrix, L is the regularization matrix, and a is the regularization parameter.

The solution Xᵢ to Eq. 1 can be approximated with the following analytical expression.

Xᵢ=(A^{T}A+αL^{T}L)⁻¹A^{T}Yᵢ, Xᵢ≥0 (2)

Assuming ε is the NMR measurement error:

Yᵢ=Y_{i,true}+ε (3)

Where Y_{i,true} is NMR log measurement at depth dᵢ without the noise contamination. Hence, without considering non-negative constraints, NMR inversion fitting error can be approximated as the following:

Yᵢ−AXᵢ≈(I−A(A^{T}A+αL^{T}L)⁻¹A^{T})Y_{i,true}+A(A^{T}A+αL^{T}L)⁻¹A^{T}ε+E (4)

The variance of the term A(A^{T}A+αL^{T}L)⁻¹A^{T} ε in Eq. 4 due to NMR measurement error ε is greatly reduced by the NMR forward modeling matrix A, such that:

Var(A(A^{T}A+αL^{T}L)⁻¹A^{T}ε)<<Var(ε) (5)

The first term A(A^{T}A+αL^{T}L)⁻¹A^{T}Y_{i,true} in Eq. 5 is the bias of NMR inversion. It can be shown that the bias can be insignificant for very small regularization parameter value α. In case of 0^{th} order regularization, and assuming {λₖ} are the singular values of NMR forward matrix A, then:

$$( I - {A ( {A}^{T} A + α {L}^{T} L )}^{- 1} {A}^{T} ) {Y}_{i , true} = α ( \begin{matrix}⋮ \\ \frac{{b}_{k}}{{λ}_{k}^{2} + α} \\ ⋮\end{matrix} ) \qquad ( 6 )$$

Where bₖ is the projection of the NMR data Y_{i,true} to k^{th} eigenvector of NMR forward matrix A. Hence:

∥(I−A(A^{T}A+αL^{T}L)⁻¹A^{T})Y_{i,true}∥<C*α∥Y_{i,true}∥ (7)

Therefore, NMR fitting error approximates to NMR measurement error ε for a very small regularization parameter value, α, as shown in Eq. 8.

Yᵢ−AXᵢ≈ε, for small α (8)

Therefore, Eq. 8 illustrates that NMR measurement errors (e.g., NMR measurement noise) can be extracted from NMR log data with a very small regularization parameter value. In some examples, the regularization parameter, αₛₘₐₗₗ, can be less than about 0.0001 to about 0.001 to ensure that the fitting error closely approximates the NMR measurement error (e.g., NMR measurement noise).

At block 206, the method 200 can include simulating NMR responses at the given depth (dᵢ) by superimposing the extracted NMR measurement noises at the adjacent depths to the NMR log data of the given depth. In some examples, simulating NMR responses can include Monte Carlo simulation methods. In some examples, simulating NMR responses can include bootstrap resampling, Bayesian inversion, simulated annealing, perturbation analysis, ensemble Kalman filtering, and/or other types of simulation methods.

At block 208, the method 200 can include determining, from the simulated NMR responses at the given depth (dᵢ), NMR T₁ and/or T₂ distributions for each of the simulated NMR responses. Determining the NMR T₁ and/or T₂ distributions can include using the regularized NMR inversion described with respect to Eq. 1-Eq. 2. In some examples, the regularization parameter used to determine the NMR T₁ and/or T₂ distributions can depend on the level of measurement noise. In some examples, the regularization parameter, α, for determining the NMR T₁ and/or T₂ distributions can be about 1 to about 10. In other examples, the regularization parameter, a, for determining the NMR T₁ and/or T₂ distributions can be determined based on certain criterion. For example, the criterion can include a balance between the fitting error and the regularization term, or a balance between NMR T₁ or T₂ spectral resolution and uncertainty.

At block 210, the method 200 can include determining, via the NMR T₁ and/or T₂ distributions, an NMR spectral uncertainty for the given depth (dᵢ). For example, an ensemble NMR T₁ and/or T₂ distributions is formed from the simulated NMR responses. Statistical analysis can be conducted on the ensemble of NMR T₁ and/or T₂ distributions to determine mean NMR T₁ and/or T₂ distributions and a standard deviation for the NMR T₁ and/or T₂ distributions. The standard deviation can be the NMR spectral uncertainty for the given depth. In some examples, the statistical analysis can include determining the mean, mode, median, variance, standard deviation, entropy, kurtosis, skewness, percentiles (e.g., probabilistic bounds), confidence intervals, and/or other statistical results from the ensemble of NMR T₁ and/or T₂ distributions. In some examples, the statistical analysis can include performing t-tests, analysis of variance, z-tests, non-parametric methods (e.g., Wilcoxon signed-rank, Mann-Whitney U test, and/or Kruskal-Wallis test), f-tests, coefficients of variation tests, Bayesian credible intervals tests, goodness-of-fit tests (e.g., chi-square, Kolomogrov-Smirnov, Shapiro-Wilk), and/or other statistical analysis.

The method 200 can be repeated to determine the NMR spectral uncertainty for a plurality of depths. In this manner, the NMR spectral uncertainty can be determined for every depth within the NMR log data, thereby providing real-time comprehensive uncertainty estimations at each depth within a wellbore.

In some examples, the methods described herein can be used to address multiparameter domain uncertainty, such as 2D or 3D NMR. In some examples, the methods described herein can incorporate both T₁ and T₂ uncertainties to derive a T₁-T₂ map uncertainty.

The mean NMR T₁ and/or T₂ distributions can provide petrophysical information related to the formation surrounding the wellbore. For example, NMR T₁ and/or T₂ distributions can provide information related to pore size, fluid type, and saturation of the formation. The mean NMR T₁ and T₂ distributions determined by the method 200 can provide more accurate information related to the petrophysical properties than previous NMR inversion techniques by taking into account NMR measurement noises of adjacent depths, as described herein. Further, the NMR spectral uncertainty can provide information to an operator to assess a level of risk in the accuracy of the NMR T₁ and/or T₂ distributions.

At block 212, the method 200 can include determining a drilling path for a wellbore and/or a perforation interval based on the NMR T₁ and/or T₂ distributions and the NMR spectral uncertainty. In some examples, the drilling path and/or perforation interval is determined based on the mean NMR T₁ and/or T₂ distributions described herein. The NMR T₁ and/or T₂ distributions and the NMR spectral uncertainty can provide information related to the petrophysical properties of the wellbore. For example, the NMR T₂ spectral uncertainty can be used to determine the uncertainty of partial porosities (e.g., micro, meso, and macro porosities). In this manner, drilling paths and/or perforation intervals can be determined to optimize the drilling operation.

In some examples, the method 200 can be conducted by removing the effect of the regularization term. For example, at block 202, the method 200 can be conducted by removing the regularization matrix L. By using a sufficiently small regularization parameter, the effect of the regularization term on NMR spectral uncertainty estimation can be removed.

Further provided herein is a system for performing the method 200. The system can include the NMR measurement device and at least one processor (e.g., the computing system described herein). The NMR measurement device can be operable to measure NMR log data, as described herein. The at least one processor can be operable to perform the steps of the method 200.

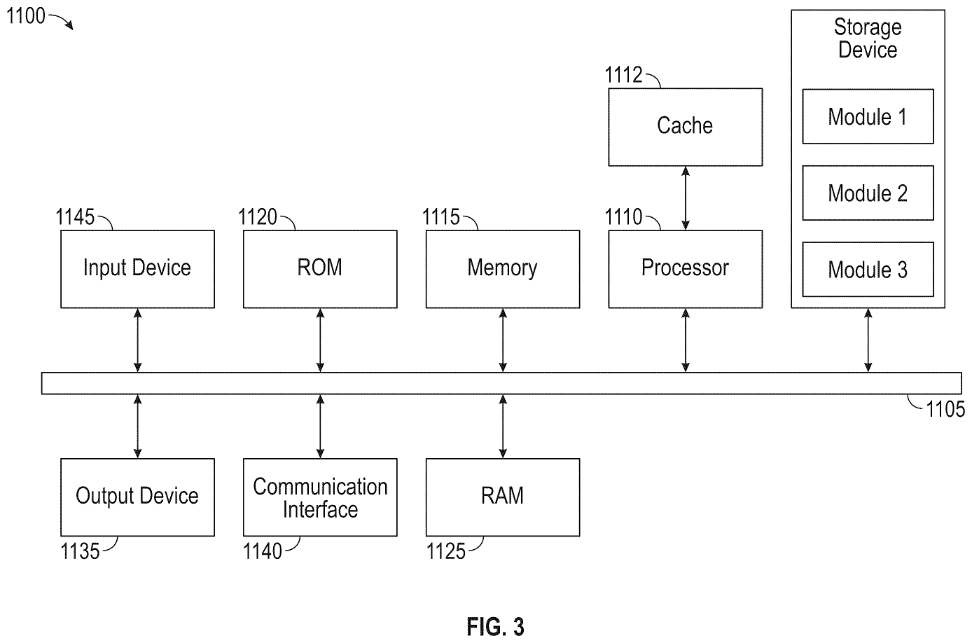

FIG. 3 is a diagram illustrating an example of a system for implementing certain aspects of the present technology. In particular, FIG. 3 illustrates an example of computing system 1100, which can be for example any computing device making up internal computing system, a remote computing system, a camera, or any component thereof in which the components of the system are in communication with each other using connection 1105. Connection 1105 can be a physical connection using a bus, or a direct connection into processor 1110, such as in a chipset architecture. Connection 1105 can also be a virtual connection, networked connection, or logical connection.

In some aspects, computing system 1100 is a distributed system in which the functions described in this disclosure can be distributed within a datacenter, multiple data centers, a peer network, etc. In some aspects, one or more of the described system components represents many such components each performing some or all of the function for which the component is described. In some aspects, the components can be physical or virtual devices.

Example computing system 1100 includes at least one processing unit (CPU or processor) 1110 and connection 1105 that couples various system components including system memory 1115, such as read only memory (ROM) 1120 and read only memory (RAM) 1125 to processor 1110. Computing system 1100 can include a cache 1112 of high-speed memory connected directly with, in close proximity to, or integrated as part of processor 1110.

Processor 1110 can include any general purpose processor and a hardware service or software service, such as services 1132, 1134, and 1136 stored in storage device 1130, configured to control processor 1110 as well as a special-purpose processor where software instructions are incorporated into the actual processor design. Processor 1110 may essentially be a completely self-contained computing system, containing multiple cores or processors, a bus, memory controller, cache, etc. A multi-core processor may be symmetric or asymmetric.

To enable user interaction, computing system 1100 includes an input device 1145, which can represent any number of input mechanisms, such as a microphone for speech, a touch-sensitive screen for gesture or graphical input, keyboard, mouse, motion input, speech, etc. Computing system 1100 can also include output device 1135, which can be one or more of a number of output mechanisms. In some instances, multimodal systems can enable a user to provide multiple types of input/output to communicate with computing system 1100. Computing system 1100 can include communications interface 1140, which can generally govern and manage the user input and system output. The communication interface may perform or facilitate receipt and/or transmission wired or wireless communications using wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a Bluetooth® wireless signal transfer, a BLE wireless signal transfer, an IBEACON® wireless signal transfer, an RFID wireless signal transfer, near-field communications (NFC) wireless signal transfer, dedicated short range communication (DSRC) wireless signal transfer, 802.11 WiFi wireless signal transfer, WLAN signal transfer, Visible Light Communication (VLC), Worldwide Interoperability for Microwave Access (WiMAX), IR communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 1140 may also include one or more Global Navigation Satellite System (GNSS) receivers or transceivers that are used to determine a location of the computing system 1100 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1130 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, RAM, static RAM (SRAM), dynamic RAM (DRAM), ROM, programmable read-only memory (PROM), erasable programmable read-only memory (EPROM), electrically erasable programmable read-only memory (EEPROM), flash EPROM (FLASHEPROM), cache memory (L1/L2/L3/L4/L5/L#), resistive random-access memory (RRAM/ReRAM), phase change memory (PCM), spin transfer torque RAM (STT-RAM), another memory chip or cartridge, and/or a combination thereof.

The storage device 1130 can include software services, servers, services, etc., that when the code that defines such software is executed by the processor 1110, it causes the system to perform a function. In some aspects, a hardware service that performs a particular function can include the software component stored in a computer-readable medium in connection with the necessary hardware components, such as processor 1110, connection 1105, output device 1135, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as CD or DVD, flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

In some cases, the computing device or apparatus may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, one or more network interfaces configured to communicate and/or receive the data, any combination thereof, and/or other component(s). The one or more network interfaces can be configured to communicate and/or receive wired and/or wireless data, including data according to the 3G, 4G, 5G, and/or other cellular standard, data according to the Wi-Fi (802.11x) standards, data according to the Bluetooth™ standard, data according to the IP standard, and/or other types of data.

The components of the computing device can be implemented in circuitry. For example, the components can include and/or can be implemented using electronic circuits or other electronic hardware, which can include one or more programmable electronic circuits (e.g., microprocessors, GPUs, DSPs, CPUs, and/or other suitable electronic circuits), and/or can include and/or be implemented using computer software, firmware, or any combination thereof, to perform the various operations described herein.

In some aspects, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

The following examples are intended to be illustrative only, and are not intended to be, nor should they be construed as limiting in any way of the scope of the present disclosure.

### EXAMPLES

NMR relaxation time distributions (T₂ or T₁) provide essential petrophysical properties of the formation, such as total and partial porosity, permeability. However, the accuracies of the petrophysical properties derived from NMR relaxation time distribution, are highly affected by NMR log data qualities, (e.g., signal to noise ratio (SNR) of NMR logging measurements). In addition to SNR, the accuracies of NMR based petrophysical properties can also be affected by multiple other factors, including NMR activation sequences, inversion methods, and formation types.

In current practice, the uncertainties of NMR based interpretation are mainly inferred from the fitting errors of NMR regularization inversion, and the repeatability of NMR total porosities. However, the fitting errors and the uncertainty of NMR total porosity do not reveal NMR T₂ or T₁ spectral uncertainty, which is necessary to derive the uncertainties of NMR based pore typing, i.e., the partial porosities.

The uncertainty estimation of NMR based petrophysical properties are further complicated by the regularization in the current NMR inversion process. In general, the larger the regularization, the smaller the uncertainty, and vice versa. Hence, the regularization conceals the “true” uncertainty of NMR spectrum. Also, a larger regularization introduces a large bias to NMR inversion solution.

To balance the uncertainty and bias of NMR inversion, the value of the regularization parameter is usually selected to ensure the repeatability of NMR total porosity within 1.0 p.u. Again, this practice does not directly relate to NMR T₂ or T₁ spectral uncertainty, and the repeatability of NMR partial porosities.

Statistical methods, such as Simulated Annealing and Bayesian inversion have been used to circumvent the need of using regularization terms in NMR inversion and provide the “true” NMR spectral uncertainty. However, these statistical methods are computationally expensive, and time consuming. These statistical methods are not suitable for processing NMR log data in real-time.

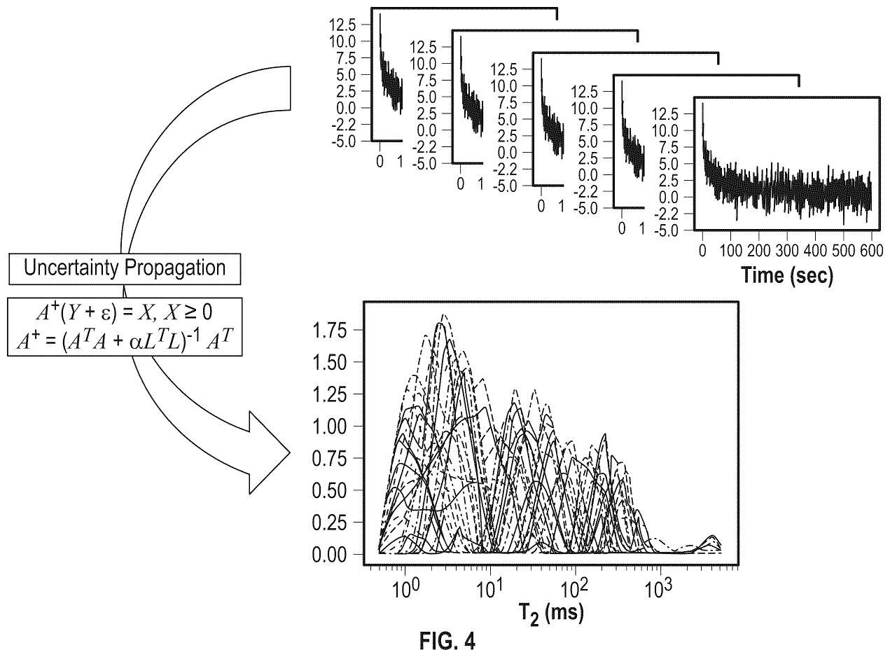

A Monte Carlo (MC) method can be used to assess the uncertainties of NMR data processing. For a given NMR data activation sequence and a pore size distribution pattern, the Monte Carlo method simulates NMR response for a specified SNR. NMR relaxation time distribution (T₂, or T₁) is then derived with NMR regularization inversion for the simulated NMR responses. The Monte Carlo simulation process is repeated multiple times to assemble the possible NMR relaxation time distributions for the specified SNR. Statistical analysis is then applied to the ensemble of NMR relaxation time distributions to estimate the NMR spectral uncertainties. FIG. 4 illustrates the workflow of using the MC method to estimate the uncertainties of NMR data processing.

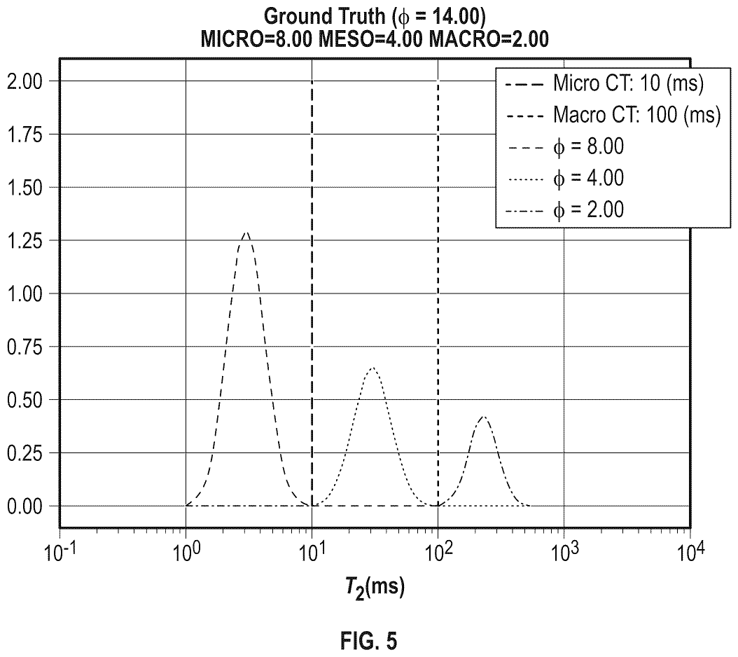

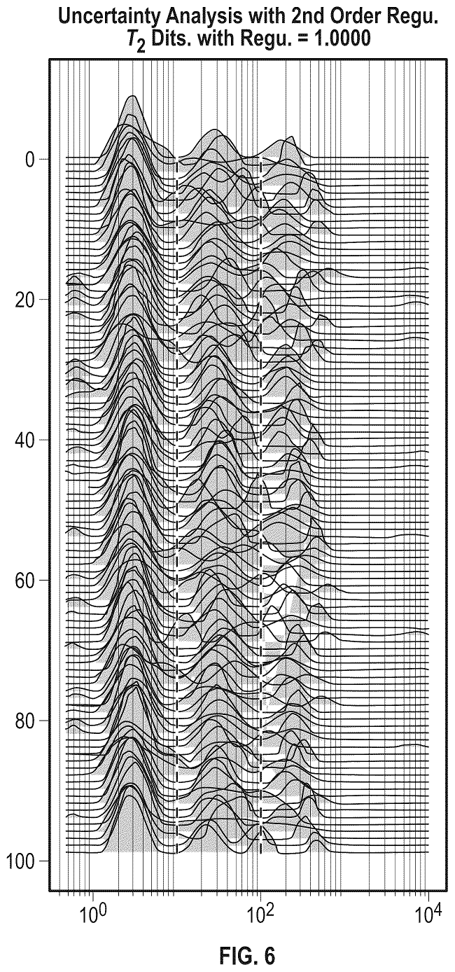

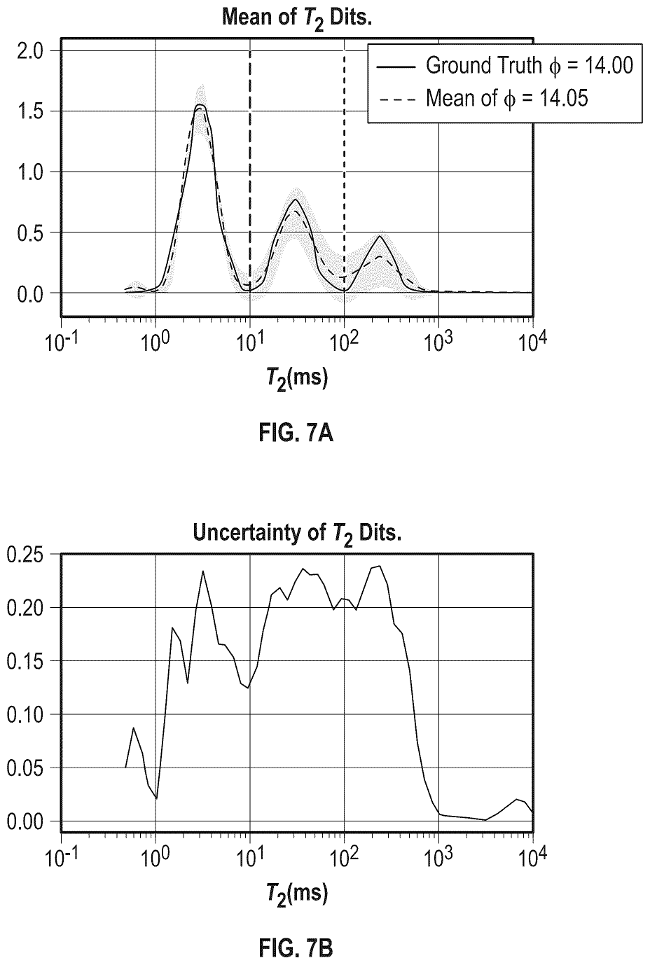

The pore size distribution pattern (ground truth) for this simulation is shown in FIG. 5. FIG. 6 shows an ensemble of simulated T₂ distributions with the NMR activation set specified in Table 1. SNR for the simulation is 10, and the regularization parameter value is 1. FIGS. 7A-7B illustrate the mean T₂ distributions and NMR spectral uncertainty estimated with MC method with the regularization parameter value of 1.

TABLE 1
Specifications of NMR Activation Set

| TW | TE | Number of | Number of |
|---|---|---|---|
| (ms) | (ms) | Echoes (NE) | Repeats |
| 10000 | 0.3 | 1800 | 1 |
| 100 | 0.3 | 200 | 16 |
| 10 | 0.3 | 20 | 160 |

In comparison to Simulated Annealing and Bayesian inversion methods, the computational cost of the Monte Carlo method is low. However, the need for repeating NMR response simulations limits the Monte Carlo method to NMR synthetic data. Therefore, the method 200 described herein adopts the Monte Carlo method to estimate uncertainties of NMR inversion and pore typing for NMR log data in real-time. Further, the method 200 can be extended to estimate the uncertainties of NMR inversion while removing the effect of regularization.

The mathematical background of NMR data processing is now described. The mathematical background described herein lays the groundwork for the method for estimating uncertainty of NMR inversion and pore typing for NMR log data in real time.

Assuming

$${\{ {Y}_{i} , {d}_{i} \}}_{i = 1}^{N}$$

are the NMR log data for a given NMR activation set, Yᵢ is NMR log response, i.e., NMR echo trains, at depth dᵢ.

$${\{ {X}_{i} \}}_{i = 1}^{N}$$

are the corresponding NMR relaxation time distributions derived from NMR log data through the regularized NMR inversion as described in Eq. 1.

$${min}_{{X}_{i} \geq 0} \{ {\vert {AX}_{i} - {Y}_{i} \vert}^{2} + α {\vert {LX}_{i} \vert}^{2} \} \qquad ( 1 )$$

Where A is NMR forward modeling matrix, L is the regularization matrix, and a is the regularization parameter.

The solution Xᵢ to Eq. 1 can be approximated with the following analytical expression.

Xᵢ=(A^{T}A+αL^{T}L)⁻¹A^{T}Yᵢ, Xᵢ≥0 (2)

Assuming ε is the NMR measurement error:

Yᵢ=Y_{i,true}+ε (3)

Where Y_{i,true} is NMR log measurement at depth dᵢ without the noise contamination. Hence, without considering non-negative constraints, NMR inversion fitting error can be approximated as the following:

Yᵢ−AXᵢ≈(I−A(A^{T}A+αL^{T}L)⁻¹A^{T})Y_{i,true}+A(A^{T}A+αL^{T}L)⁻¹A^{T}ε+ε (4)

The variance of the term A(A^{T}A+αL^{T}L)⁻¹A^{T} ε in Eq. 4 due to NMR measurement error ε is greatly reduced by the NMR forward modeling matrix A, such that:

Var(A(A^{T}A+αL^{T}L)⁻¹A^{T}ε)<<Var(ε) (5)

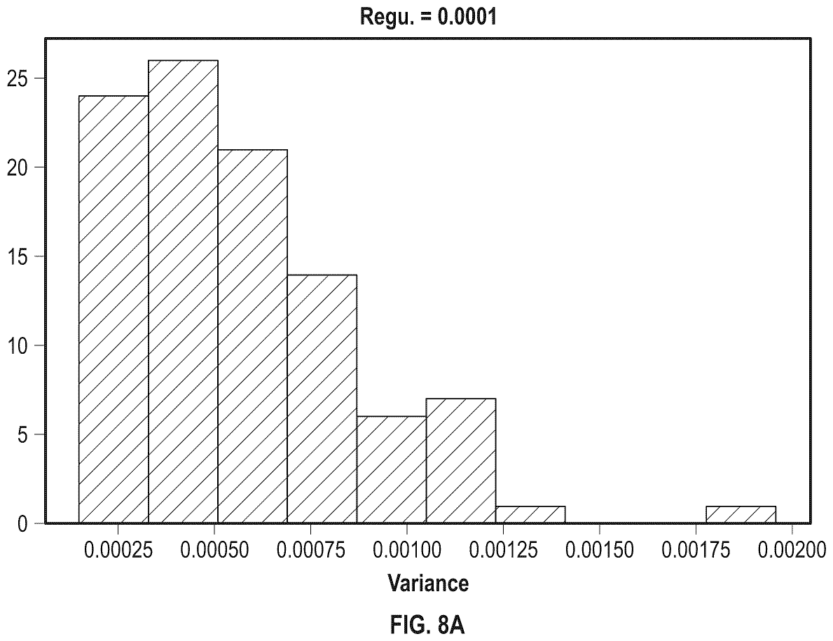

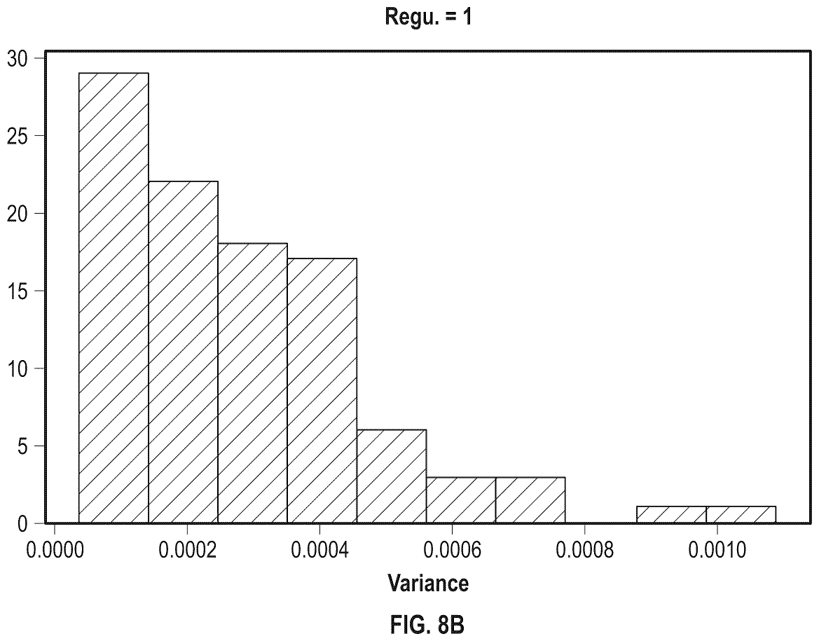

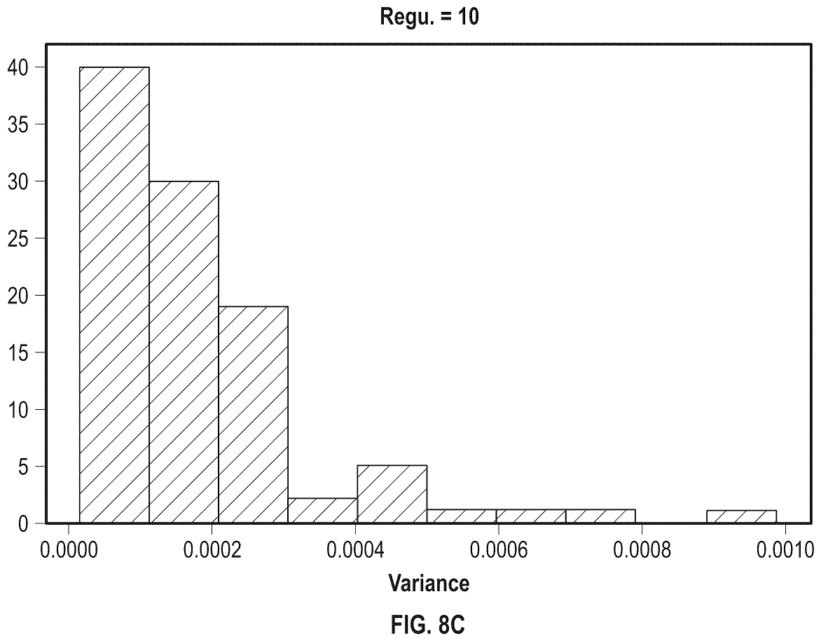

Eq. 5 can be validated with MC method as shown in FIGS. 8A-8C. The validation is based on the NMR activation set of Table 1. The variance of NMR measurement error ε is 1 p.u. FIGS. 8A-8C illustrate the variances of fitting errors with three different regularization parameter values for the echo train with TW of 10000 ms. FIGS. 8A-8C illustrate that (1) the variances of fitting error increase as regularization parameter values decrease and (2) the variances of fitting error are less significant than NMR measurement error ε.

The first term A(A^{T}A+αL^{T}L)⁻¹A^{T}Y_{i,true} in Eq. 5 is the bias of NMR inversion. It can be shown that the bias can be insignificant for very small regularization parameter value α. In case of 0^{th} order regularization, and assuming {λₖ} are the singular values of NMR forward matrix A, then:

$$( I - {A ( {A}^{T} A + α {L}^{T} L )}^{- 1} {A}^{T} ) {Y}_{i , true} = α ( \begin{matrix}⋮ \\ \frac{{b}_{k}}{{λ}_{k}^{2} + α} \\ ⋮\end{matrix} ) \qquad ( 6 )$$

Where bₖ is the projection of the NMR data Y_{i,true} to k^{th} eigenvector of NMR forward matrix A. Hence:

∥(I−A(A^{T}A+αL^{T}L)⁻¹A^{T})Y_{i,true}∥<C*α*∥Y_{i,true}∥ (7)

Therefore, NMR fitting error approximates to NMR measurement error ε for a very small regularization parameter value α, as shown in Eq. 8.

Yᵢ−AXᵢ≈ε, for small α (8)

Two implications can be derived from Eq. 8. First, NMR measurement errors can be extracted from NMR log data with a very small regularization parameter value. Second, NMR spectral uncertainties derived from the Monte Carlo method are comparable to the ones from Simulated Annealing and Bayesian inversion methods. Bayesian inversion methods use the fitting error in its likelihood distribution, and Simulated Annealing uses the fitting error in its acceptance criterion. The fitting errors in Simulated Annealing and Bayesian inversion methods are without the regularization terms.

The method 200 described herein was validated and tested against the MC method and ground truth. The method 200 can be referred to as herein as the Depth-by-Depth method.

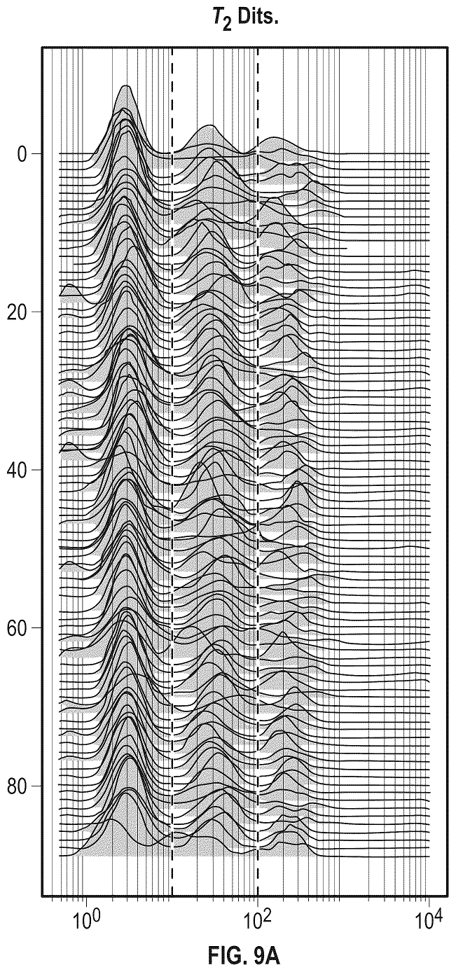

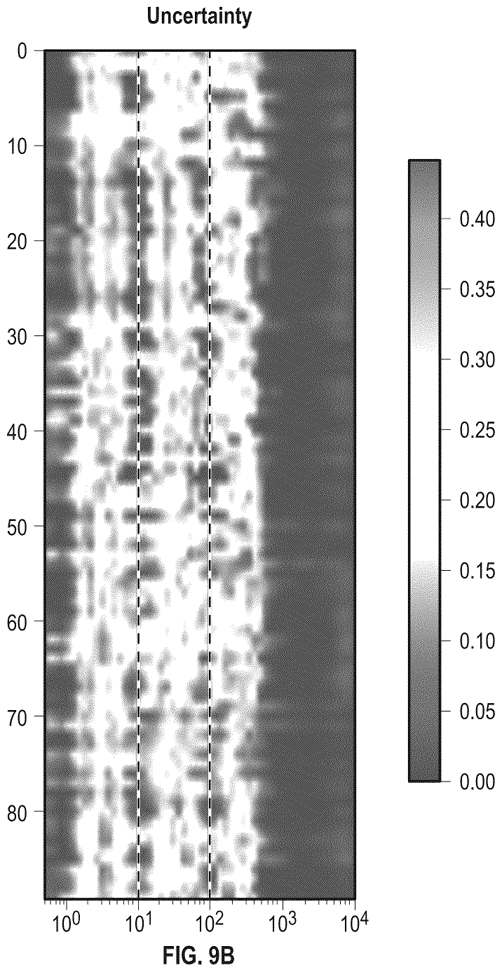

FIG. 9A illustrates the mean of T₂ distributions of the ensemble at each depth using the method 200. FIG. 9B illustrates the NMR spectral uncertainties at each depth using the method 200.

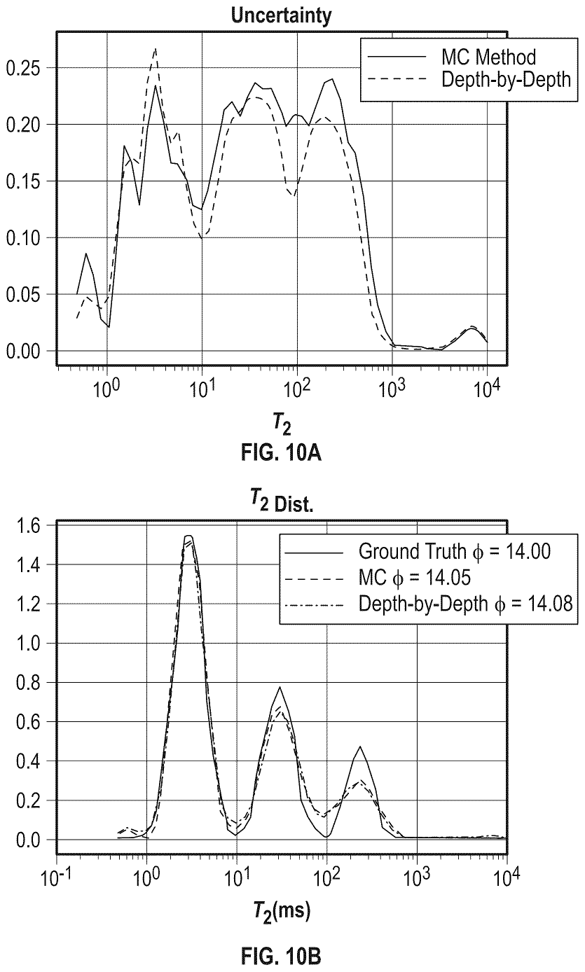

FIG. 10A illustrates that NMR spectral uncertainties for the method 200 (e.g., Depth-by-Depth method) are comparable with the one from MC method. FIG. 10A illustrates that the average of NMR spectral uncertainties from the method 200 (e.g., Depth-by-Depth method) matches well with NMR spectral uncertainty of the MC method. FIG. 10B illustrates that the mean of NMR T₂ distributions from the method 200 (e.g., Depth-by-Depth method) match very well with the mean of NMR T₂ distribution of MC method, and both the T₂ distributions from the method 200 and the MC method match well with the ground truth.

In some examples, the method 200 described herein can be conducted while removing the effect of the regularization term. The NMR spectral uncertainty is estimated with a very small regularization parameter value to ensure that the NMR inversion bias in Eq. 6 is sufficiently small.

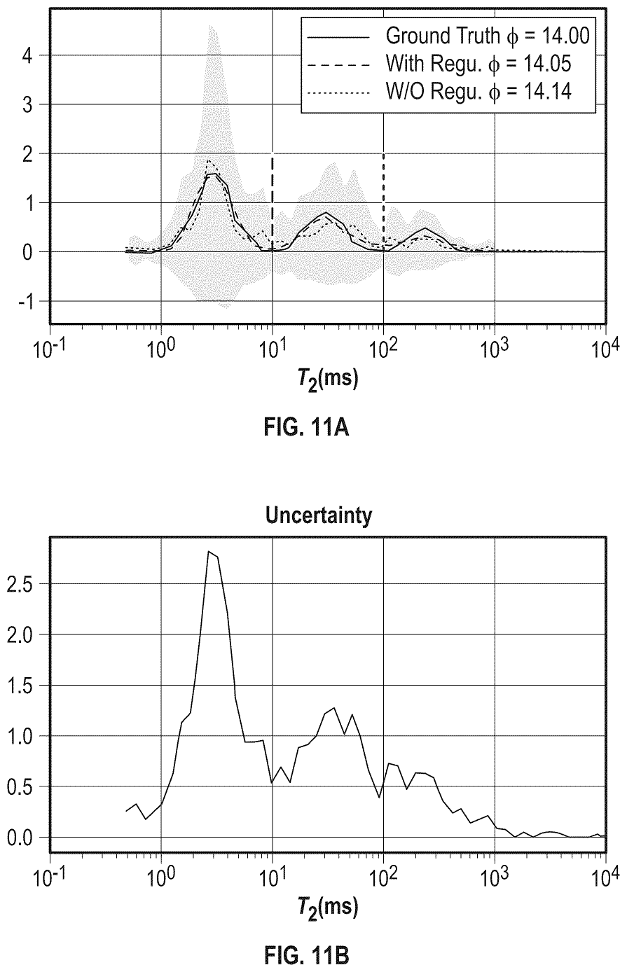

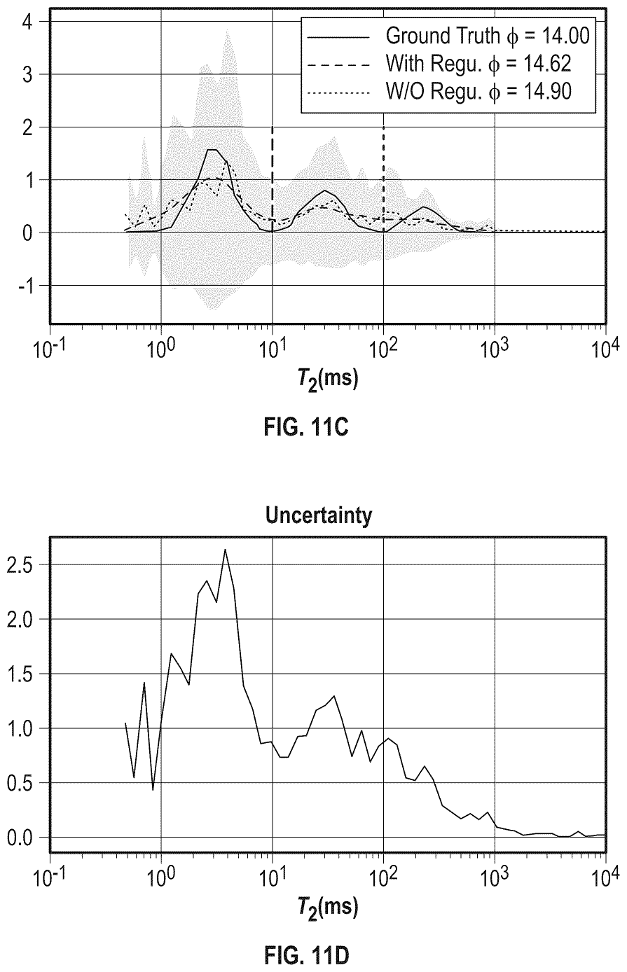

FIGS. 11A-11D illustrate NMR spectral uncertainty estimations and NMR T₂ distributions from two different NMR activation sets without considering the regularization terms. FIGS. 11A-11B are from the activation set in Table 1. FIGS. 11C-11D are from the activation set in Table 2. The activation set in Table 1 has two extra short echo trains for improving accuracies of micro porosities.

TABLE 2
Specifications of NMR Activation Set

| TW | TE | Number of | Number of |
|---|---|---|---|
| (ms) | (ms) | Echoes (NE) | Repeats |
| 10000 | 0.3 | 1800 | 1 |

FIGS. 11A-11D clearly illustrate that the uncertainties of micro porosities are reduced in the following two spectral sections for the activation set with the two extra short echo trains in Table 1. First, for the spectrum under 1 ms, the uncertainties are under 0.5 p.u. for the activation set in Table 1, while the uncertainties are over 0.5 p.u. for the activation set in Table 2. Second, for the spectrum between 1 ms. and 10 ms., the uncertainties are much narrower for the activation set in Table 1, which indicates that the spectrum resolution for the activation set in Table 1 is better than the spectrum resolution for the activation set in Table 2.

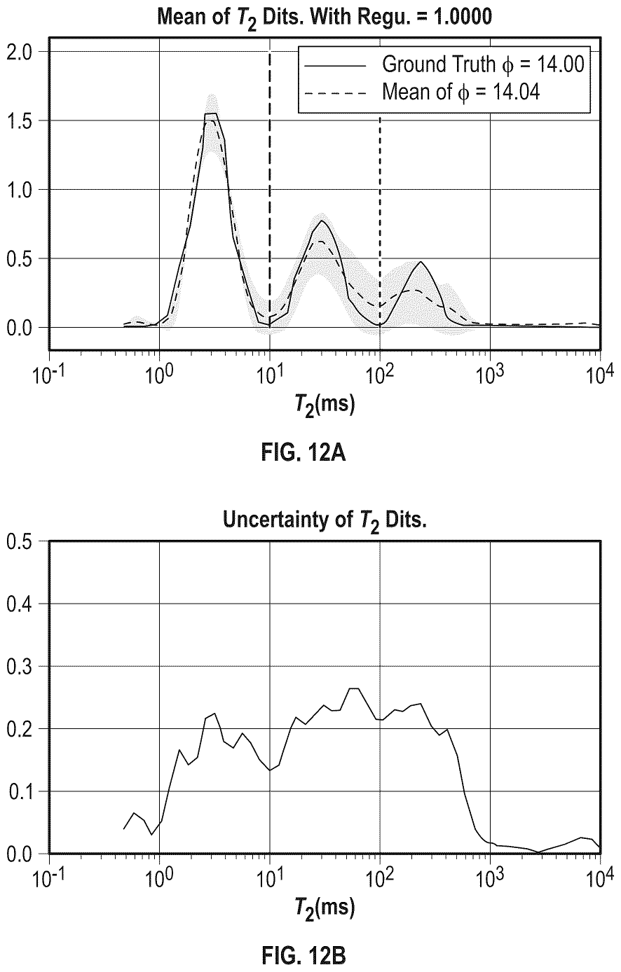

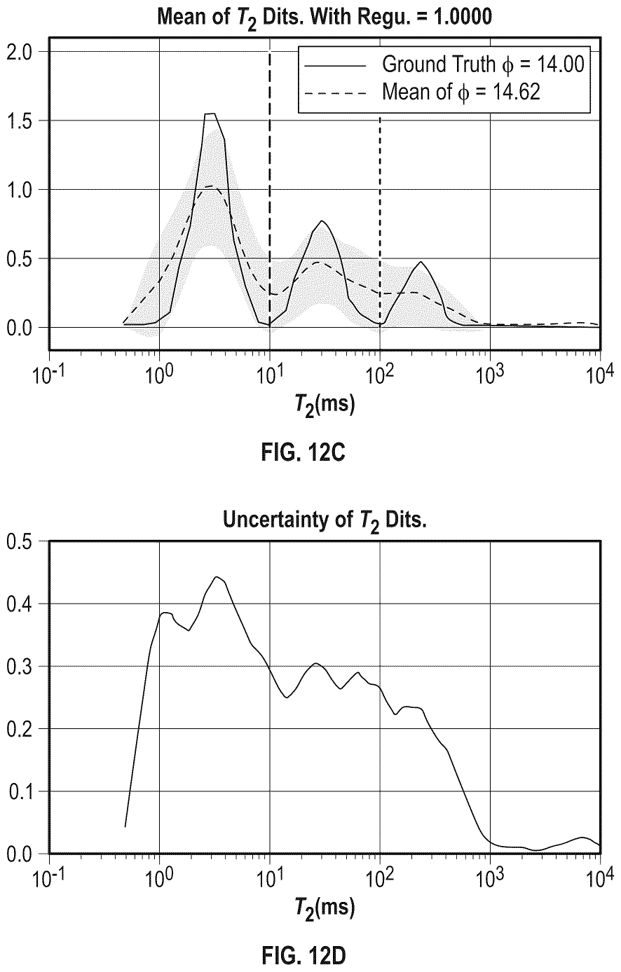

FIGS. 12A-12D illustrate NMR spectral uncertainty estimations from the two NMR activation sets with the regularization effects. The regularization parameter values are set to 1 for both activation sets. The plots in FIGS. 12A-12B are from the activation set in Table 1, and the plots in FIGS. 12C-12D are from the activation set in Table 2.

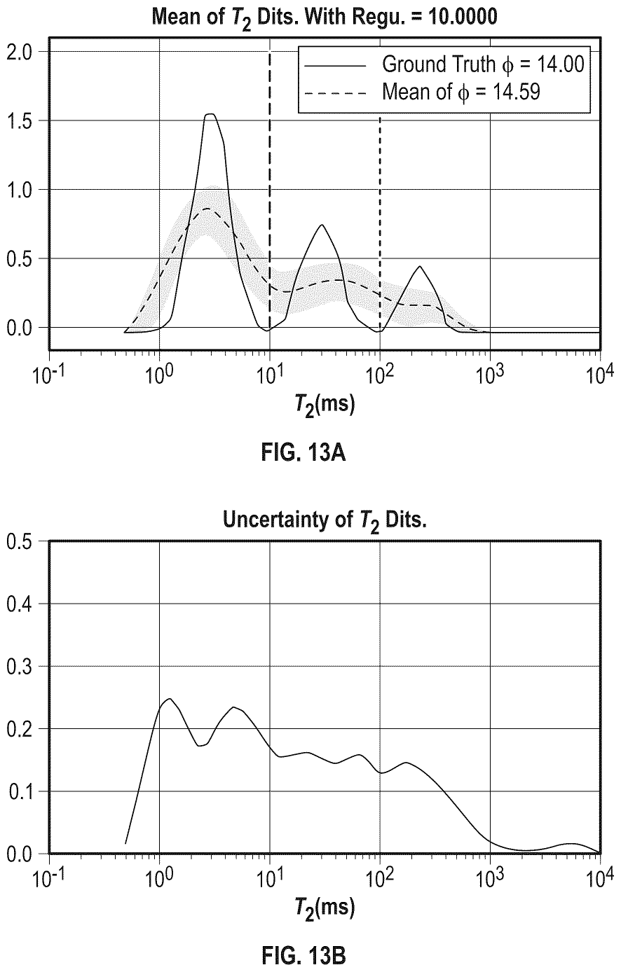

FIGS. 12A-12D illustrate that the uncertainty of the activation set in Table 1 is much less than the uncertainty of the activation set in Table 2. However, the uncertainties of the activation set in Table 2 can be reduced significantly by using a much larger regularization parameter value. FIGS. 13A-13B illustrate the uncertainties of the activation set in Table 2 with the regularization parameter value of 10.

Therefore, FIGS. 11A-13B demonstrate that the method 200 described herein (e.g., Depth-by-Depth Method) can estimate the “true” NMR spectral uncertainty concealed by the regularization terms.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure to the full extent indicated by the broad general meaning of the terms used in the attached claims. It will therefore be appreciated that the embodiments described above may be modified within the scope of the appended claims.

Numerous examples are provided herein to enhance understanding of the present disclosure. A specific set of statements are provided as follows.

Statement 1: A method for estimating nuclear magnetic resonance (NMR) spectral uncertainty in real-time, the method comprising: receiving NMR log data from an NMR measurement device; extracting, for a given depth, NMR measurement noises from the NMR log data of adjacent depths; simulating NMR responses at the given depth by superimposing the NMR measurement noises of the adjacent depths to the NMR log data of the given depth; determining, from the simulated NMR responses, NMR T1 and/or T2 distributions for each of the simulated NMR responses; determining, via the NMR T1 and/or T2 distributions, an NMR spectral uncertainty for the given depth; and determining a drilling path for a wellbore and/or a perforation interval based on the NMR T1 and/or T2 distributions and the NMR spectral uncertainty.

Statement 2: The method of statement 1, further comprising determining mean NMR T1 and/or T2 distributions from the NMR T1 and/or T2 distributions, wherein the mean NMR T1 and/or T2 distributions are used to determine the drilling path for the wellbore and/or the perforation interval.

Statement 3: The method of statement 1, wherein the NMR measurement noises are approximated with fitting errors of NMR regularization inversions having a regularization parameter.

Statement 4: The method of statement 3, wherein the regularization parameter is less than 0.001.

Statement 5: The method of statement 1, wherein determining the NMR T1 and/or T2 distributions includes using a regularized NMR inversion having a regularization parameter.

Statement 6: The method of statement 5, wherein the regularization parameter is about 1 to about 10.

Statement 7: The method of statement 1, wherein determining the NMR spectral uncertainty includes conducting a statistical analysis on the NMR T1 and/or T2 distributions.

Statement 8: A system for estimating nuclear magnetic resonance (NMR) spectral uncertainty in real-time, the system comprising: an NMR measurement device configured to measure NMR log data; and at least one processor configured to: receive the NMR log data; extract, for a given depth, NMR measurement noises from the NMR log data of adjacent depths; simulate NMR responses at the given depth by superimposing the NMR measurement noises of the adjacent depths to the NMR log data of the given depth; determine, from the simulated NMR responses, NMR T1 and/or T2 distributions for each of the simulated NMR response; determine, via the NMR T1 and/or T2 distributions, an NMR spectral uncertainty; and determine a drilling path for a wellbore and/or a perforation interval based on the NMR T1 and/or T2 distributions and the NMR spectral uncertainty.

Statement 9: The system of statement 8, wherein the at least one processor is further configured to determine mean NMR T1 and/or T2 distributions from the NMR T1 and/or T2 distributions, wherein the mean NMR T1 and/or T2 distributions are used to determine the drilling path for the wellbore and/or the perforation interval.

Statement 10: The system of statement 8, wherein the NMR measurement noises are approximated with fitting errors of NMR regularization inversions having a regularization parameter.

Statement 11: The system of statement 10, wherein the regularization parameter is less than 0.001.

Statement 12: The system of statement 8, wherein determining the NMR T1 and/or T2 distributions includes using a regularized NMR inversion having a regularization parameter.

Statement 13: The system of statement 12, wherein the regularization parameter is about 1 to about 10.

Statement 14: The system of statement 8, wherein determining the NMR spectral uncertainty includes conducting a statistical analysis on the NMR T1 and/or T2 distributions.

Statement 15: A non-transitory computer readable medium, having instructions stored thereon, that when executed by at least one computing device cause the at least one computing device to perform operations for estimating nuclear magnetic resonance (NMR) spectral uncertainty in real-time, the operations comprising: receiving NMR log data from an NMR measurement device; extracting, for a given depth, NMR measurement noises from the NMR log data of adjacent depths; simulating NMR responses at the given depth by superimposing the NMR measurement noises of the adjacent depths to the NMR data for the given depth; determining, from the simulated NMR responses, NMR T1 and/or T2 distributions for each of the simulated NMR responses; determining, via the NMR T1 and/or T2 distributions, an NMR spectral uncertainty for the given depth; and determining a drilling path for a wellbore and/or a perforation interval based on the NMR T1 and/or T2 distributions and the NMR spectral uncertainty.

Statement 16: The non-transitory computer readable medium of statement 15, wherein the operations further include determining mean NMR T1 and/or T2 distributions from the NMR T1 and/or T2 distributions, wherein the mean NMR T1 and/or T2 distributions are used to determine the drilling path for the wellbore and/or the perforation interval.

Statement 17: The non-transitory computer readable medium of statement 15, wherein the NMR measurement noises are approximated with fitting errors of NMR regularization inversions having a regularization parameter, and wherein the regularization parameter is less than 0.001.

Statement 18: The non-transitory computer readable medium of statement 15, wherein determining the NMR T1 and/or T2 distributions includes using a regularized NMR inversion having a regularization parameter.

Statement 19: The non-transitory computer readable medium of statement 18, wherein the regularization parameter is about 1 to about 10.

Statement 20: The non-transitory computer readable medium of statement 15, wherein determining the NMR spectral uncertainty includes conducting a statistical analysis on the NMR T1 and/or T2 distributions.

What is claimed is:

1. A method for estimating nuclear magnetic resonance (NMR) spectral uncertainty in real-time, the method comprising:
receiving NMR log data from an NMR measurement device;
extracting, for a given depth, NMR measurement noises from the NMR log data of adjacent depths;
simulating NMR responses at the given depth by superimposing the NMR measurement noises of the adjacent depths to the NMR log data of the given depth;
determining, from the simulated NMR responses, NMR T₁ and/or T₂ distributions for each of the simulated NMR responses;
determining, via the NMR T₁ and/or T₂ distributions, an NMR spectral uncertainty for the given depth; and
determining a drilling path for a wellbore and/or a perforation interval based on the NMR T₁ and/or T₂ distributions and the NMR spectral uncertainty.

2. The method of claim 1, further comprising conducting statistical analysis on the NMR T₁ and/or T₂ distributions, wherein results of the statistical analysis of the NMR T₁ and/or T₂ distributions are used to determine the drilling path for the wellbore and/or the perforation interval.

3. The method of claim 1, wherein the NMR measurement noises are approximated with fitting errors of NMR regularization inversions having a regularization parameter.

4. The method of claim 3, wherein the regularization parameter is less than 0.001.

5. The method of claim 1, wherein determining the NMR T₁ and/or T₂ distributions includes using a regularized NMR inversion having a regularization parameter.

6. The method of claim 5, wherein the regularization parameter is about 1 to about 10.

7. The method of claim 1, wherein determining the NMR spectral uncertainty includes conducting a statistical analysis on the NMR T₁ and/or T₂ distributions.

8. A system for estimating nuclear magnetic resonance (NMR) spectral uncertainty in real-time, the system comprising:
an NMR measurement device configured to measure NMR log data; and
at least one processor configured to:
receive the NMR log data;
extract, for a given depth, NMR measurement noises from the NMR log data of adjacent depths;
simulate NMR responses at the given depth by superimposing the NMR measurement noises of the adjacent depths to the NMR log data of the given depth;
determine, from the simulated NMR responses, NMR T₁ and/or T₂ distributions for each of the simulated NMR responses;
determine, via the NMR T₁ and/or T₂ distributions, an NMR spectral uncertainty; and
determine a drilling path for a wellbore and/or a perforation interval based on the NMR T₁ and/or T₂ distributions and the NMR spectral uncertainty.

9. The system of claim 8, wherein the at least one processor is further configured to conduct statistical analysis on the NMR T₁ and/or T₂ distributions, wherein results of the statistical analysis are used to determine the drilling path for the wellbore and/or the perforation interval.

10. The system of claim 8, wherein the NMR measurement noises are approximated with fitting errors of NMR regularization inversions having a regularization parameter.

11. The system of claim 10, wherein the regularization parameter is less than 0.001.

12. The system of claim 8, wherein determining the NMR T₁ and/or T₂ distributions includes using a regularized NMR inversion having a regularization parameter.

13. The system of claim 12, wherein the regularization parameter is about 1 to about 10.

14. The system of claim 8, wherein determining the NMR spectral uncertainty includes conducting a statistical analysis on the NMR T₁ and/or T₂ distributions.

15. A non-transitory computer readable medium, having instructions stored thereon, that when executed by at least one computing device cause the at least one computing device to perform operations for estimating nuclear magnetic resonance (NMR) spectral uncertainty in real-time, the operations comprising:
receiving NMR log data from an NMR measurement device;
extracting, for a given depth, NMR measurement noises from the NMR log data of adjacent depths;
simulating NMR responses at the given depth by superimposing the NMR measurement noises of the adjacent depths to the NMR data for the given depth;
determining, from the simulated NMR responses, NMR T₁ and/or T₂ distributions for each of the simulated NMR responses;
determining, via the NMR T₁ and/or T₂ distributions, an NMR spectral uncertainty for the given depth; and
determining a drilling path for a wellbore and/or a perforation interval based on the NMR T₁ and/or T₂ distributions and the NMR spectral uncertainty.

16. The non-transitory computer readable medium of claim 15, wherein the operations further include conducting statistical analysis on the NMR T₁ and/or T₂ distributions, wherein results of the statistical analysis are used to determine the drilling path for the wellbore and/or the perforation interval.

17. The non-transitory computer readable medium of claim 15, wherein the NMR measurement noises are approximated with fitting errors of NMR regularization inversions having a regularization parameter, and wherein the regularization parameter is less than 0.001.

18. The non-transitory computer readable medium of claim 15, wherein determining the NMR T₁ and/or T₂ distributions includes using a regularized NMR inversion having a regularization parameter.

19. The non-transitory computer readable medium of claim 18, wherein the regularization parameter is about 1 to about 10.

20. The non-transitory computer readable medium of claim 15, wherein determining the NMR spectral uncertainty includes conducting a statistical analysis on the NMR T₁ and/or T₂ distributions.
